(19) United States
(12) Patent Application Publication
(10) Pub. No.: US 2026/0371983 A1
(43) Pub. Date: Nov. 19, 2026

(54) FLOW RECTIFICATION DEVICE

(71) Applicant: ACM RESEARCH (SHANGHAI), INC., Shanghai (CN)

(72) Inventors: Xuefei Deng, Shanghai (CN); Cheng Cheng, Shanghai (CN)

(73) Assignee: ACM RESEARCH (SHANGHAI), INC., Shanghai (CN)

(21) Appl. No.: 19/135,058

(22) PCT Filed: Nov. 30, 2023
(86) PCT No.: PCT/CN2023/135567

§ 371 Date: Jun. 2, 2025

(30) Foreign Application Priority Data
Dec. 2, 2022 (CN) 202211541793.9

(51) Int. Cl. H10P 72/00

(52) U.S. Cl. CPC H10P 72/0402; H10P 72/0432

(57) ABSTRACT

The present invention relates to the field of integrated circuit chip manufacturing, in particular to a flow rectification device, comprising a cover body, a gas inlet distribution plate, a diffusion plate, a gas inlet pipe and a gas discharge pipe. The gas inlet distribution plate is arranged above the diffusion plate. The gas inlet pipe and the gas discharge pipe are arranged on the cover body. A first chamber is formed between the upper surface of the gas inlet distribution plate and the inner wall of the cover body. A second chamber is formed between the lower surface of the diffusion plate and the substrate. A third chamber is formed between the lower surface of the gas inlet distribution plate and the upper surface of the diffusion plate.

### FIELD OF THE INVENTION

The present invention relates to the field of integrated circuit chip manufacturing, in particular to a flow rectification device.

### BACKGROUND

Chip manufacturing includes photolithography process, and coating and heating are indispensable processes in the photolithography process. In the progress of heating the substrate that has completed the coating process, the external gas is introduced into the heating device. It is necessary to ensure that the high-temperature external gas (such as N₂) heated by the hotplate (HP) can uniformly flow through the surface of the substrate, thereby uniformly removing the organic gas evaporated from the coating, preventing the organic gas from accumulating above the coating to result in the nonuniform distribution of the coating along the radial direction of the substrate. Therefore, the uniformity of the gas flow rate above the substrate is very important. However, how to improve the uniformity of the gas flow rate above the substrate is an urgent problem to be solved at present.

### SUMMARY

In view of the above-described problems in the prior art, an object of the present invention is to provide a flow rectification device for improving the uniformity of the gas volume distribution above the substrate.

In order to achieve the above object, the present invention provides the following technical solutions:

A flow rectification device, comprising a cover body, a gas inlet distribution plate, a diffusion plate, a gas inlet pipe and a gas discharge pipe, the gas inlet distribution plate being arranged above the diffusion plate, the gas inlet pipe and the gas discharge pipe being arranged on the cover body. A substrate is capable of being placed below the diffusion plate.

A first chamber is formed between the upper surface of the gas inlet distribution plate and the inner wall of the cover body, a second chamber is capable of being formed between the lower surface of the diffusion plate and the substrate, and a third chamber is formed between the center region of the lower surface of the gas inlet distribution plate and the upper surface of the diffusion plate.

One end of the gas inlet pipe is used for connecting an external gas source, and the other end is communicated with the first chamber, one end of the gas discharge pipe is used for connecting to an external gas extraction device, and the other end is communicated with the third chamber.

The gas inlet distribution plate is provided with a plurality of gas inlet holes, and the diffusion plate is provided with a plurality of through-holes, wherein after the external gas sequentially flows through the first chamber, the gas inlet holes, the second chamber, the through-holes and the third chamber through the gas inlet pipe, the external gas is discharged to the outside through the gas discharge pipe.

The depth of the through-holes is set according to the flow rate of the gas flowing through the through-holes, and the depth of the through-holes having high gas flow rate is larger than the depth of the through-holes having low gas flow rate.

The present invention also provides a heating device, comprising a flow rectification device and a heating assembly. The flow rectification device covers the heating assembly to form a closed space, for disposing the substrate. The heating assembly is used for heating the substrate.

Compared with the prior art, the present invention has the following beneficial effects:

The flow rectification device provided by the present invention comprises a gas inlet distribution plate, a diffusion plate, a cover body, a gas inlet pipe and a gas discharge pipe. Wherein, the diffusion plate is provided with a plurality of through-holes, and the external gas flows through the gas inlet distribution plate through the gas inlet pipe and flows to the surface of the substrate. The gas flowing above the surface of the substrate is discharged to the gas discharge pipe through a plurality of through-holes. The depth of the through-holes is set according to the flow rate of the gas flowing through the through-holes. The depth of the through-holes having the high gas flow rate is larger than the depth of the through-holes having the low gas flow rate. The large depth of the through-holes can hinder the discharge of the external gas and the volatile gas to a certain extent, and increasing the depth of the through-holes having the high gas flow rate can reduce the flow of the external gas into the through-holes. Correspondingly, the reduced part of the external gas can gather at the position of through-holes with small depth and the external gas can be discharged. The small depth of the through-holes is more conducive to the discharge of the external gas and the volatile gas, so as to balance the distribution amount of the external gas above the substrate. Through the above structural design, the uniform distribution of the external gas above the substrate can be finally realized in the whole process. The external gas and the volatile gas can be uniformly discharged from the diffusion plate.

### BRIEF DESCRIPTION OF THE DRAWINGS

In order to more clearly explain the embodiments of the present invention or the technical solutions in the prior art, the drawings that need to be used in the description of the embodiments or the prior art will be briefly introduced below. It is obvious that the drawings in the following description are only some embodiments of the present invention, and for those of ordinary skill in the art, other drawings can be obtained according to these drawings under the premise without making creative efforts.

FIG. 1 is a schematic structural view of a heating device according to the present invention;

FIG. 2 is a partial sectional view of a heating device according to the present invention;

FIG. 3 is a schematic sectional view of a flow rectification device according to an embodiment of the present invention;

FIG. 4 is a schematic sectional view of a flow rectification device according to another embodiment of the present invention;

FIG. 5 is a schematic sectional view of a flow rectification device according to yet another embodiment of the present invention;

FIG. 6 is a top view of a diffusion plate according to an embodiment of the present invention;

FIG. 7 is a top view of a gas inlet distribution plate according to an embodiment of the present invention;

FIG. 8 is a schematic sectional view of a flow rectification device according to yet another embodiment of the present invention;

FIG. 9 is an enlarged schematic view of part A of FIG. 8;

FIG. 10 is an enlarged schematic view of part B of FIG. 8;

FIG. 11 is a comparison diagram of the flow rate distribution of a diffusion plate.

[Figure Number Description]: the cover body 1, the gas inlet distribution plate 2, the diffusion plate 3, the substrate 4, the gas inlet pipe 5, the gas discharge pipe 6, the heating plate 7, the guiding rings 8, the bonding portions 9, the first chamber 11, the second chamber 12, the third chamber 13, the gas inlet holes 21, the connecting columns 22 and the through-holes 31.

### PREFERRED EMBODIMENTS OF THE INVENTION

In order to make the objects, features and advantages of the present invention more obvious and easier to understand, the technical solutions in the embodiments of the present invention will be clearly and completely described below with reference to the accompanying drawings in the embodiments of the present invention. It is obvious that the embodiments described below are only some embodiments of the present invention, but not all embodiments. Based on the embodiments in the present invention, all other embodiments obtained by those of ordinary skill in the art under the premise without making creative efforts belong to the scope of protection of the present invention.

In the description of the present invention, it is to be understood that when one component is considered to be “connected” to the other component, it may be directly connected to the other component or there may be a component disposed in the center at the same time. When a component is considered to be “disposed” on the other component, it may be a component disposed directly on the other component or there may be a component disposed in the center at the same time.

Hereinafter, the technical solutions of the present invention will be further described with reference to the accompanying drawings and specific embodiments.

### First Embodiment

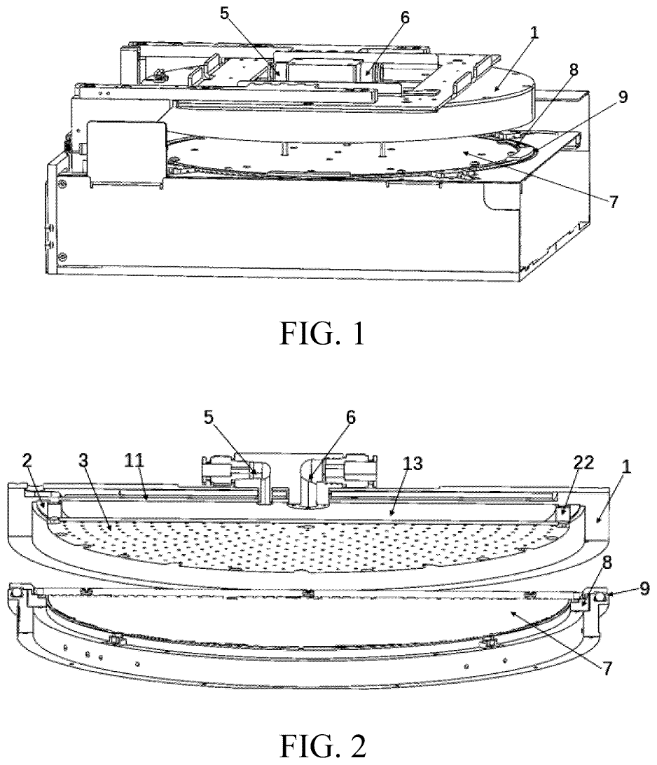

Please refer to FIGS. 1-3, an embodiment of the present invention provides a heating device, comprising a flow rectification device and a heating assembly. The flow rectification device covers the heating assembly to form the closed space. The substrate 4 is located in the closed space, and the heating assembly is used for heating the substrate 4.

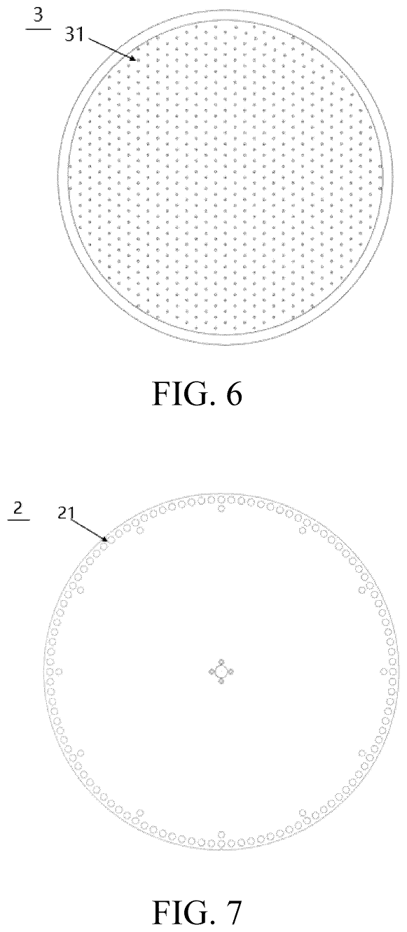

The flow rectification device comprises a cover body 1, a gas inlet distribution plate 2, a diffusion plate 3, a gas inlet pipe 5 and a gas discharge pipe 6. The gas inlet pipe 5 and the gas discharge pipe 6 are mounted on the cover body 1. Furthermore, the gas inlet distribution plate 2, the diffusion plate 3 and the cover body 1 are connected together by a connector. Optionally, the connector is a bolt, a screw, or the like. A plurality of screws are used to pass through the edge of the diffusion plate 3, the edge of the gas inlet distribution plate 2 and the upper part of the cover body 1 to connect the three sections. Referring to FIG. 6, the diffusion plate 3 is uniformly provided with a plurality of through-holes 31.

The gas inlet distribution plate 2 is provided with connecting columns 22, and the diffusion plate 3 and the gas inlet distribution plate 2 are connected by the connecting columns 22. Referring to FIG. 7, the gas inlet distribution plate 2 comprises an edge region and a center region, and the edge region is provided around the outer periphery of the center region. A plurality of gas inlet holes 21 are provided in the edge region of the gas inlet distribution plate 2. In the present embodiment, the range of the edge region of the gas inlet distribution plate 2 is a region defined by the connecting columns 22 to the inner wall of the cover body 1. The remaining region of the gas inlet distribution plate 2 is a central region of the gas inlet distribution plate 2. Of course, the connecting columns 22 are not limited to the arrangement mode of the present embodiment, and the connecting columns 22 may be arranged in the direction close to the center of the gas inlet distribution plate 2.

The heating assembly comprises a heating plate 7, guiding rings 8 and bonding portions 9. The outer periphery of the heating plate 7 is snapped on the guiding rings 8, and the substrate 4 is above the heating plate 7. The cover body 1 covers the bonding portions 9 to form the closed space. The gas inlet distribution plate 2, the diffusion plate 3 and the substrate 4 are all in the closed space.

A first chamber 11 is formed between the upper surface of the gas inlet distribution plate 2 and the inner wall of the cover body 1. A second chamber 12 is formed between the lower surface of the diffusion plate 3 and the substrate 4. A third chamber 13 is formed between the center region of the lower surface of the gas inlet distribution plate 2 and the upper surface of the diffusion plate 3.

One end of the gas inlet pipe 5 is connected to the external gas source, for transmitting the external gas into the flow rectification device. The other end of the gas inlet pipe 5 is communicated with the first chamber 11. The gas discharge pipe 6 passes out of the gas inlet distribution plate 2 and is arranged above the diffusion plate 3. One end of the gas discharge pipe 6 is connected to an external gas extraction device, and the other end is communicated with the third chamber 13. In addition, the nozzle of the gas discharge pipe 6 and the center of the diffusion plate 3 are provided correspondingly.

When the external gas extraction device works, the gas discharge pipe 6 has a large suction force to the third chamber 13. The external gas sequentially flows through the first chamber 11, the gas inlet holes 21, the second chamber 12, the through-holes 31, the third chamber 13 through the gas inlet pipe 5. Finally, the external gas is discharged to the outside through the gas discharge pipe 6. When the external gas is in the second chamber 12, the external gas can carry the volatile gas together to flow to the third chamber 13 and carry the volatile gas away to the outside of the flow rectification device. Optionally, in the present embodiment, the external gas is N₂.

The diffusion plate 3 comprises an edge region and a center region. The center region of the diffusion plate 3 is arranged correspondingly to the gas discharge pipe 6, and the edge region surrounds the periphery of the center region. Since the gas discharge pipe 6 has a larger suction force to the center region of the diffusion plate 3 than on the edge region, most of the N2 can be accumulated in the center region of the diffusion plate 3. And the volatile gas can be carried out from the through-holes 31 of the center region of the diffusion plate 3. Hence, the volatile gas present above the edge region of the substrate 4 can be difficult to be carried away. The arrangement of the gas discharge pipe 6 corresponding to the center region of the diffusion plate 3 brings the large suction force, so that the gas flow rate of the through-holes 31 in the center region of the diffusion plate 3 is higher than the gas flow rate of the through-holes 31 in the edge region.

Therefore, the embodiment of the present invention designs that the depth of the through-holes 31 increases progressively along the edge region to the center region of the diffusion plate 3, that is, the depth of the through-holes 31 having the high gas flow rate is larger than the depth of the through-holes 31 having the low gas flow rate. The through-holes 31 with different depths have different resistance to the gas discharge, so that the quantity of flow of the gas in the through-holes 31 in the edge region and in the center region of the diffusion plate 3 tends to be consistent, thereby causing the flow rate flowing through the throughs-holes 31 at all places tends to be consistent. The N2 uniformly takes away the organic gas volatilized from the coating, so that the coating can be uniformly distributed along the radial direction of the substrate 4.

A plurality of through-holes 31 of the diffusion plate 3 are set to different depths. The through-holes 31 in the central region have the large depths, and the volatile gas and a part of the N2 can be hindered to be discharged to a certain extent, so that the N2 can be gathered to the edge region. The through-holes 31 in the edge region have the small depths, which is beneficial to the discharge of the N2 and the volatile gas. The uniformity of the N2 distribution in the second chamber 12 can be improved. The flow rate of the gas in the through-holes 31 in the edge region and in the central region of the diffusion plate 3 tends to be consistent.

Optionally, the entire circle of the gas inlet holes 21 is provided in the edge region of the gas inlet distribution plate 2. Optionally, the gas inlet holes 21 are not limited to the edge region of the gas inlet distribution plate 2, and the gas inlet holes 21 may be provided in the center region of the gas inlet distribution plate 2. The relative position between the nozzle of the gas discharge pipe 6 and the diffusion plate 3 is not limited to the above, and optionally, the nozzle of the gas discharge pipe 6 and the edge of the diffusion plate 3 are provided correspondingly.

In the embodiment of the present invention, the depth of the through-holes 31 increases linearly along the edge region to the center region of the diffusion plate 3. Furthermore, the depth of the through-holes 31 in the edge region also increases linearly along the direction from the edge region to the center region. The depth of the through-holes 31 in the center region also increases linearly along the direction from the center region to the center of the diffusion plate 3. The coefficients of the linear increases at both places are the same, and the cross section of the diffusion plate 3 is similar to the shape of circular table. Optionally, the depth of the through-holes 31 is adjusted according to the change of the flow rate, and the coefficients of the two linear increases may be different.

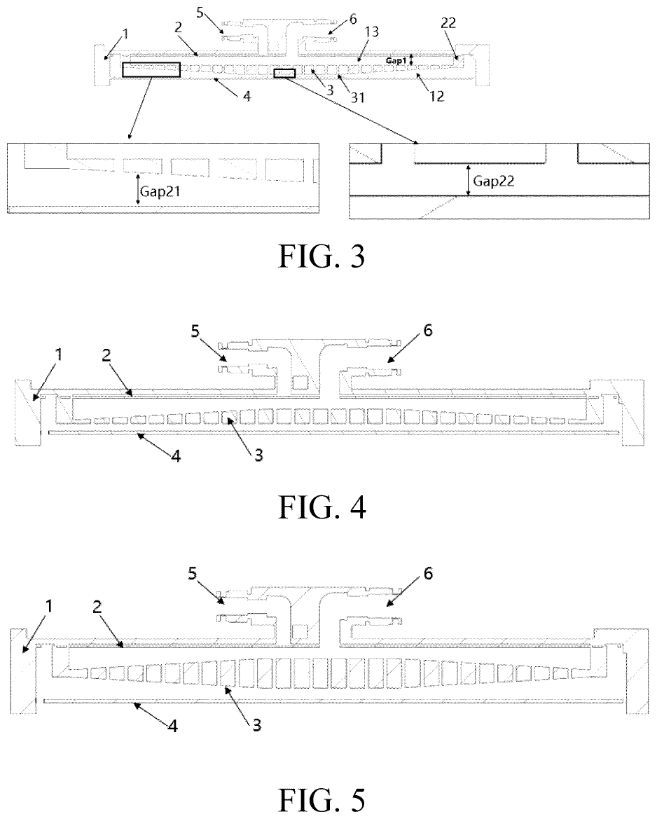

Specifically, with continued reference to FIG. 3, FIG. 3 is a schematic sectional view of the flow rectification device through the center point of the diffusion plate 3. The distance between the upper surface of the diffusion plate 3 and the gas inlet distribution plate 2 is Gap1, and the Gap1 between all the through-holes 31 and the gas inlet distribution plate 2 is the same. The distance between the lower surface of the diffusion plate 3 in the edge region and the substrate 4 is Gap21, and the distance between the lower surface of the diffusion plate 3 in the center region and the substrate 4 is Gap22. The distance between the through-holes 31 on the diffusion plate 3 and the substrate 4 changes linearly. In the present embodiment, Gap21 is 2 to 10 mm, and Gap22 is 1 to 5 mm.

The depth of the through-holes 31 in the edge region of the diffusion plate 3 is smaller than the depth of the through-holes 31 in the center region. And the distance Gap21 between the lower surface of the diffusion plate 3 in the edge region and the substrate 4 is larger than the distance Gap22 between the lower surface of the diffusion plate 3 in the center region and the substrate 4. Since the Gap 21 is large, the amount of N2 staying above the edge region of the substrate 4 increases, and the discharge of the volatile gas in the edge region of the substrate 4 can be further promoted. Gap22 is small, which reduces the amount of N2 staying above the center region to a certain extent, thereby further equalizing the amount of N2 staying at both the center region and the edge region. The uniformity of the flow rate of N2 at various positions above the substrate 4 throughout the whole process can be further improved.

In an optional embodiment, as shown in FIG. 4, FIG. 4 is a schematic sectional view of the flow rectification device through the center point of the diffusion plate 3. The distance between the upper surface of the diffusion plate 3 in the edge region and the gas inlet distribution plate 2 is larger than the distance between the upper surface of the diffusion plate 3 in the center region and the gas inlet distribution plate 2. Optionally, the distance between the lower surface of the diffusion plate 3 in the edge region and in the center region and the substrate 4 can be kept consistent.

In an optional embodiment, as shown in FIG. 5, FIG. 5 is a schematic sectional view of the flow rectification device through the center point of the diffusion plate 3. The distance between the edge region of the upper surface of the diffusion plate 3 and the gas inlet distribution plate 2 is larger than the distance between the center region of the upper surface of the diffusion plate 3 and the gas inlet distribution plate 2. Meanwhile, the distance between the lower surface of the diffusion plate 3 in the edge region and the substrate 4 is larger than the distance between the lower surface of the diffusion plate 3 in the center region and the substrate 4.

In an optional embodiment, as shown in FIG. 6, the through-holes 31 on the diffusion plate 3 are uniformly arranged, and the adjacent through-holes 31 are spaced apart by the same distance. Three adjacent through-holes 31 are arranged in the shape of regular triangular.

The layout of the through-holes 31 is not limited to the above-described layout. Optionally, a plurality of through-holes 31 on the diffusion plate 3 are arranged in the form of a plurality of virtual concentric circles. The depth of each through-hole 31 on one concentric circle is the same, and the depth of the through-holes 31 on different concentric circles is different. Optionally, according to the flow rate distribution of each region, the aperture size of each through-hole 31 on one concentric circle is the same, and the aperture size of each through-hole 31 on different concentric circles is set differently.

### Second Embodiment

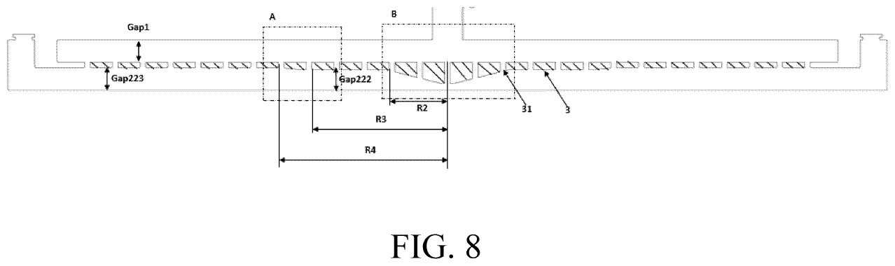

Please refer to FIGS. 8-10, the difference between this embodiment and the first embodiment is that the depth of the through-holes 31 of the diffusion plate 3 increases stepwise from the edge region to the center region of the diffusion plate 3. The depth of the through-holes 31 is the same in each position of the edge region.

The distance between the upper surface of the diffusion plate 3 and the gas inlet distribution plate 2 is Gap1, and the distance Gap1 between all the through-holes 31 and the gas inlet distribution plate 2 is the same.

Since the edge region is farther than the nozzle of the gas discharge pipe 6, the arrangement of the position of the gas discharge pipe 6 has little influence on the edge region. The gas flow rate of the through-holes 31 in each position of the edge region is substantially equal, so that the depth of the through-holes 31 in each position of the edge region is set to be equal. However, the position of the gas discharge pipe 6 has a large influence on the center region, and there is a significant difference in the gas flow rate of the through-holes 31 in each position of the center region. Hence, it is necessary to further improve the uniformity of the through-holes 31 in each position of the center region.

The center region of the diffusion plate 3 comprises a first center region, a second center region, a third center region and a fourth center region which are sequentially arranged around the center of the diffusion plate 3 from the inside to the outside. The depth of the through-holes 31 corresponding to the fourth center region, the third center region, the second center region and the first center region increases sequentially.

As shown in FIGS. 8-10, the second center region, the third center region and the fourth center region are all annular regions. The radius of the first center region is R1, that is, the length of the farthest boundary of the first center region to the center of the diffusion plate 3 is R1, the length of the farthest boundary of the second center region to the center of the diffusion plate 3 is R2, the length of the farthest boundary of the third center region to the center of the diffusion plate 3 is R3, and the length of the farthest boundary of the fourth center region to the center of the diffusion plate 3 is R4. The distance between the lower surface of the diffusion plate 3 in the first center region and the substrate 4 is Gap221, the distance between the lower surface of the diffusion plate 3 in the third center region and the substrate 4 is Gap222, and the distance between the lower surface of the diffusion plate 3 in the region where the radius of the edge region is larger than R4 and the substrate 4 is Gap223. The distance between each position of the lower surface of the diffusion plate 3 in the first center region and the substrate 4 tends to be consistent, and the distance between each position of the lower surface of the diffusion plate 3 in the third center region and the substrate 4 tends to be consistent.

In the direction from the edge region to the center region, the distance between the lower surface of the diffusion plate 3 in the second center region and in the fourth center region and the substrate 4 decreases linearly, and the depth of the through-holes 31 in the second center region and in the fourth center region increases linearly.

Furthermore, the distance between the through-holes 31 in the second center region and the center of the diffusion plate 3 is in a linear relationship with the depth of the through-holes 31. As shown in FIG. 10, the inclination angle formed between the lower surface of the diffusion plate 3 and the horizontal plane in the second center region is θ1,

$$tan θ 1 = \frac{Gap 222 - Gap 221}{R 2 - R 1}$$

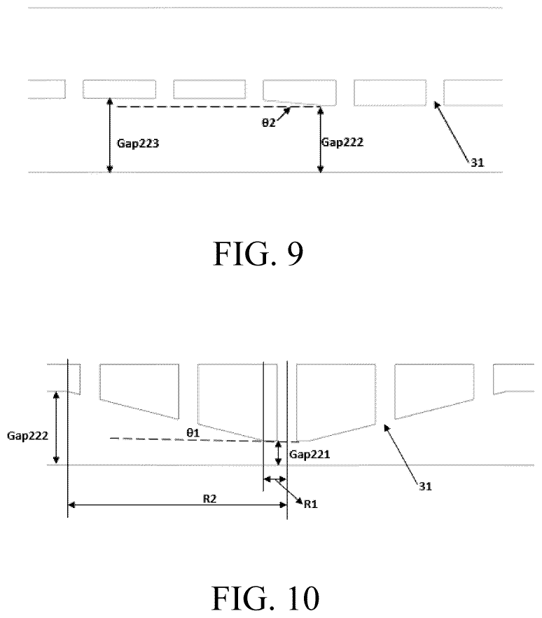

The distance between the through-holes 31 in the fourth center region and the center of the diffusion plate 3 is in a linear relationship with the depth of the through-holes 31. As shown in FIG. 9, the inclination angle formed between the lower surface of the diffusion plate 3 and the horizontal plane in the fourth center region is θ2,

$$tan θ 2 = \frac{Gap 223 - Gap 222}{R 4 - R 3}$$

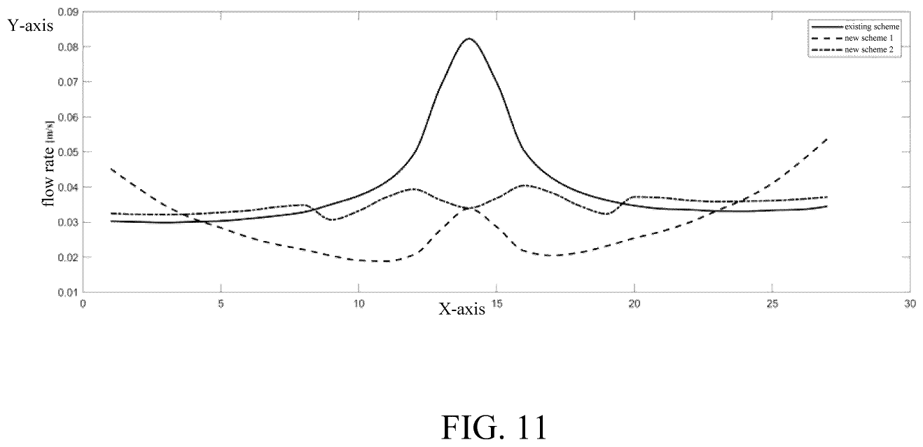

Referring to FIG. 11, FIG. 11 shows a comparison diagram of the flow rate distribution of the diffusion plate 3. The X-axis represents the position of each through-hole on the cross-sectional plane through the center of the diffusion plate, and the Y-axis represents the flow rate of the through-holes. The new scheme 1 is a flow rate distribution curve of the flow rectification device of the first embodiment, and the new scheme 2 is a flow rate distribution curve of the flow rectification device of the second embodiment. The existing scheme is a flow rate distribution curve of the existing flow rectification device. In the drawing, in the existing flow rectification device, the flow rate of the through-holes 31 in the center region of the diffusion plate 3 is much higher than the flow rate in the edge region, while the uniformity of the flow rate of the through-holes 31 on the diffusion plate 3 of the present invention is better. Wherein, the uniformity of the flow rate in the flow rectification device of embodiment 2 is the best.

In order to further improve the uniformity of the flow rate of each position of the diffusion plate 3, the depth of the through-holes 31 is set according to the flow rate flowing through the through-holes 31. The depth of the through-holes 31 having the high flow rate is larger than the depth of the through-holes 31 having the low flow rate. Further increasing the depth of the through-holes 31 in the position where the flow rate is high in the figure, and decreasing the depth of the through-holes 31 in the position where the flow rate is low in the figure, so that the flow rate of each through-hole 31 can be finally on the horizontal line. The uniformity of the flow rate of the diffusion plate 3 can be higher.

Furthermore, the existing diffusion plate is compared with the similar circular mesa-shaped diffusion plate 3 mentioned in the present invention. The uniformity of the flow rate between the existing diffusion plate and the diffusion plate of the present invention can be analyzed under the given flow rate condition. The uniformity can be judged by 3σ. 3σ is a concept of mathematical statistics, meaning 3 times the standard deviation, which represents the dispersion degree of the data and is used to express the uniformity. Compared with the existing diffusion plate, the diffusion plate 3 having the circular mesa-shaped structure of the present invention has a smaller calculated 3σ value and better uniformity.

| | Gap1 | Gap21 | Gap22 | 3σ |
|---|---|---|---|---|
| Existing Scheme | 8 mm | 8.2 mm | 8.2 mm | 1.2108 |
| New Scheme 1 | 8 mm | 8.2 mm | 2.2 mm | 0.9245 |

In an optional embodiment, when the total intake of the gas flow rate of the N2 increases, in order to stabilize the uniformity of the flow rate of the diffusion plate 3, the distance between the lower surface of the diffusion plate 3 and the substrate 4 can be continuously reduced. Furthermore, the aperture of the through-holes 31 can be reduced, and the uniformity of the flow rate of the diffusion plate 3 can be further improved.

The above-described embodiments are merely used to describe the technical solutions of the present invention, and are not intended to limit the technical solutions. Although the present invention has been described in detail with reference to the aforementioned embodiments, those of ordinary skill in the art should understand that the technical solutions described in the aforementioned embodiments may still be modified or some technical features may be equivalently replaced. However, these modifications or substitutions do not deviate the essence of the corresponding technical solutions from the spirit and scope of the technical solutions of each embodiment of the present invention.

1. A flow rectification device, comprising a cover body, a gas inlet distribution plate, a diffusion plate, a gas inlet pipe and a gas discharge pipe, the gas inlet distribution plate being arranged above the diffusion plate, a substrate being capable of being placed below the diffusion plate, and the gas inlet pipe and the gas discharge pipe being arranged on the cover body;
a first chamber being formed between the upper surface of the gas inlet distribution plate and the inner wall of the cover body, a second chamber capable of being formed between the lower surface of the diffusion plate and the substrate, and a third chamber being formed between the lower surface of the gas inlet distribution plate and the upper surface of the diffusion plate;
one end of the gas inlet pipe being used for connecting an external gas source, and the other end being communicated with the first chamber, one end of the gas discharge pipe being used for connecting to an external gas extraction device, and the other end being communicated with the third chamber;
a plurality of gas inlet holes being provided on the gas inlet distribution plate, a plurality of through-holes being provided on the diffusion plate, wherein the external gas flows through the first chamber, the gas inlet holes, the second chamber, the through-holes and the third chamber sequentially through the gas inlet pipe and then is discharged to the outside through the gas discharge pipe;
the depth of the through-holes being set according to the flow rate of the gas flowing through the through-holes, and the depth of the through-holes having high gas flow rate being larger than the depth of the through-holes having low gas flow rate.

2. The flow rectification device according to claim 1, wherein the nozzle of the gas discharge pipe and the center of the diffusion plate are arranged correspondingly, the diffusion plate comprises an edge region and a center region, the edge region surrounds the periphery of the center region, the depth of the through-holes of the edge region is smaller than the depth of the through-holes of the center region.

3. The flow rectification device according to claim 1, wherein a plurality of gas inlet holes are provided in the edge region of the gas inlet distribution plate, the external gas flows through the gas inlet holes through the gas inlet pipe and flows towards the surface of the substrate.

4. The flow rectification device according to claim 2, wherein the depth of the through-holes increases linearly along the edge region to the center region.

5. The flow rectification device according to claim 4, wherein the depths of the through-holes in the edge region and in the center region both increase linearly along the direction from the edge region to the center region.

6. The flow rectification device according to claim 2, wherein the depth of the through-holes increases stepwise along the edge region to the center region.

7. The flow rectification device according to claim 2, wherein the distance between the upper surface of the diffusion plate in the edge region and the gas inlet distribution plate is larger than the distance between the upper surface of the diffusion plate in the center region and the gas inlet distribution plate.

8. The flow rectification device according to claim 7, wherein the distance between the lower surface of the diffusion plate in the edge region and the substrate is larger than or equal to the distance between the lower surface of the diffusion plate in the center region and the substrate.

9. The flow rectification device according to claim 2, wherein the distance between the lower surface of the diffusion plate in the edge region and the substrate is larger than the distance between the lower surface of the diffusion plate in the center region and the substrate.

10. The flow rectification device according to claim 9, wherein both the distances between the upper surface of the diffusion plate in the edge region and in the center region and the gas inlet distribution plate are consistent.

11. The flow rectification device according to claim 6, wherein the center region comprises a first center region, a second center region, a third center region and a fourth center region arranged sequentially from the inside to the outside around the center of the diffusion plate;
the depth of the through-holes corresponding to the fourth center region, the third center region, the second center region and the first center region increases stepwise sequentially.

12. The flow rectification device according to claim 11, wherein the depths of the through-holes corresponding to the second center region and the fourth center region both increase linearly along the direction from the edge region to the center region.

13. The flow rectification device according to claim 11, wherein the through-holes are of the same depth in all positions in the first center region, and the through-holes are of the same depth in all positions in the third center region.

14. The flow rectification device according to claim 13, wherein the distance between each position of the lower surface of the diffusion plate in the first center region and the substrate are consistent, and the distance between each position of the lower surface of the diffusion plate in the third center region and the substrate are consistent.

15. The flow rectification device according to claim 12, wherein the distance between the lower surface of the diffusion plate in the second center region and in the fourth center region and the substrate decreases linearly along the direction from the edge region to the center region.

16. The flow rectification device according to claim 11, wherein the through-holes are of the same depth in all positions of the edge region.

17. The flow rectification device according to claim 11, wherein the distance between each position of the upper surface of the diffusion plate and the gas inlet distribution plate are the same.

18. The flow rectification device according to claim 1, wherein the adjacent through-holes are spaced apart by the same distance.

19. The flow rectification device according to claim 18, wherein the three adjacent through-holes are arranged in the regular triangular arrangement.

20. The flow rectification device according to claim 18, wherein a plurality of through-holes are arranged in the form of a plurality of virtual concentric circles.

21. The flow rectification device according to claim 20, wherein the depth of each through-hole on one concentric circle are the same, and the depth of the through-holes on the different concentric circles are different.

22. The flow rectification device according to claim 21, wherein the aperture of each through-hole on one concentric circle are the same, and the apertures of the through-holes on different concentric circles are different.

23. A heating device, comprising a flow rectification device as claimed in claim 1 and a heating assembly, the flow rectification device covering the heating assembly to form a closed space for disposing the substrate, the heating assembly being used for heating the substrate.

24. The heating device according to claim 23, wherein the heating assembly comprises a heating plate, a guiding ring and a bonding portion, the outer periphery of the heating plate is snapped on the guiding ring, the substrate is adapted to be disposed on the heating plate, the cover body covers the bonding portion to form the closed space, and the gas inlet distribution plate and the diffusion plate are both in the closed space.
